(19) United States
(12) Patent Application Publication
(10) Pub. No.: US 2011/0175757 A1
(43) Pub. Date: Jul. 21, 2011

(54) APPARATUS AND METHOD FOR IMPROVING KEY SCAN PERFORMANCE USING INVERTER CIRCUIT IN PORTABLE TERMINAL

(75) Inventor: Kwang-Min KIL, Suwon-si (KR)

(73) Assignee: SAMSUNG ELECTRONICS CO. LTD., Suwon-si (KR)

(21) Appl. No.: 13/006,713

(22) Filed: Jan. 14, 2011

(30) Foreign Application Priority Data
Jan. 18, 2010 (KR) 10-2010-0004223

(51) Int. Cl. H03M 11/00

(52) U.S. Cl. 341/26

(57) ABSTRACT

An apparatus and a method for key scan in a portable terminal, more specifically, an apparatus and a method for enhancing a key scan process which recognizes a user's key press by defining key inputs corresponding to state of a plurality of input signals and allowing a plurality of key scans with a limited number of General Purpose Input/Outputs (GPIOs) are provided. The apparatus includes a controller for setting one or more intervals for a key scan process, for classifying a state of a signal input in each interval as one of a first state and a second state, and for setting one of a plurality of different functions according to the state and the interval of the input signal, and a key input determiner for, when detecting a key input of a user during the key scan process, recognizing one of a plurality of different key inputs according to the state of the input signal, and for determining a function corresponding to the recognized key input. The controller performs the determined function.

### PRIORITY

This application claims the benefit under 35 U.S.C. §119(a) of a Korean patent application filed in the Korean Intellectual Property Office on Jan. 18, 2010, and assigned Serial No. 10-2010-0004223, the entire disclosure of which is hereby incorporated by reference.

### BACKGROUND OF THE INVENTION

1. Field of the Invention

The present invention relates to an apparatus and a method for a key scan of a portable terminal. More particularly, the present invention relates to an apparatus and a method for performing a plurality of functions using a limited number of General Purpose Input/Outputs (GPIOs) by defining key inputs corresponding to a state of a plurality of input signals in the portable terminal.

2. Description of the Related Art

The use of portable terminals is ubiquitous among people of all ages and both sexes in modern society. The portable terminals are used as a medium for wireless voice communication and information exchange.

Historically, the portable terminals only featured portability and wireless communication. As technologies of the portable terminal evolved, service providers and terminal manufacturers began competitively exploiting products or services so as to distinguish their portable terminals from those of other competitors.

For example, the portable terminal has evolved into a multimedia device that includes a phone book, games, a Short Message Service (SMS), Electronic (E)-mail, morning calls, a Motion Picture Expert Group (MPEG)-1 or MPEG-2 Audio Layer-3 (MP3) player, schedule management, a digital camera, and a wireless internet service, and thus provides various services.

Such a portable terminal includes a key input device such as keypad, for interfacing with a user.

In general, the portable terminal determines the key input by the user for a given function, using a matrix-type keypad. The matrix-type keypad includes an input port for inputting a key scan signal to a microprocessor, and an output port for outputting a control signal of the microprocessor. The matrix-type keypad determines the key pressed by the user by detecting the key scan based on electrical resistance.

However, as the functions of the portable terminal are added, the number of the GPIOs being used increases.

For example, use of a QWERTY keypad applied to the portable terminal has been increasing. To implement the QWERTY keypad, a number of GPIOs are used that corresponds to the number of the keys of the keyboard. However, since the portable terminal is only provided with a limited number of GPIOs, it is difficult to extend the GPIOs as the functions of the portable terminal increase.

Since the extension of the GPIOs can raise the cost of the portable terminal, an apparatus and a method for efficiently using a limited number of GPIOs are desired.

### SUMMARY OF THE INVENTION

An aspect of the present invention is to address at least the above-mentioned problems and/or disadvantages and to provide at least the advantages described below. Accordingly, an aspect of the present invention is to provide an apparatus and a method for improving a key scan process to recognize a user's key press in a portable terminal.

Another aspect of the present invention is to provide an apparatus and a method for allowing a plurality of key scans with a limited number of GPIOs in a portable terminal.

Yet another aspect of the present invention is to provide an apparatus and a method for defining key inputs corresponding to a state of a plurality of input signals in a portable terminal.

In accordance with an aspect of the present invention, an apparatus for improving performance of a key scan in a portable terminal is provided. The apparatus includes a controller for setting one or more intervals for a key scan process, for classifying a state of a signal input in each interval as one of a first state and a second state, and for setting one of a plurality of different functions according to the state and the interval of the input signal, and a key input determiner for, when detecting a key input of a user during the key scan process, recognizing one of a plurality of different key inputs according to the state of the input signal, and for determining a function corresponding to the recognized key input. The controller performs the determined function.

In accordance with another aspect of the present invention, a method for improving performance of a key scan in a portable terminal is provided. The method includes setting one or more intervals for a key scan process, classifying a state of a signal input into each interval as one of a first state and a second state, setting one of a plurality of different functions according to the state and the interval of an input signal, when detecting a key input of a user during the key scan process, recognizing one of a plurality of different key inputs according to the state of the input signal, and performing a function corresponding to the recognized key input.

In accordance with yet another aspect of the present invention, a method for improving performance of a key scan in a portable terminal is provided. The method includes associating a different function with each of a plurality of states of a key input signal input during each of a plurality of intervals, determining a function corresponding to the state and the interval of a key input signal input during the key scan, and performing the determined function.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 is a block diagram of a portable terminal for recognizing a user's key input through key scan according to an exemplary embodiment of the present invention;

FIG. 2 is a diagram of a key input determiner according to an exemplary embodiment of the present invention;

FIG. 3 is a flowchart of a method for recognizing the user's key input through a key scan in a portable terminal according to an exemplary embodiment of the present invention; and

FIG. 4 is a diagram for comparing a key scan method according to an exemplary embodiment of the present invention with a key scan method according to the related art.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Exemplary embodiments of the present invention provide an apparatus and a method for improving a key scan process to recognize a user's key press by defining a key input which performs a different operation according to an input signal state and allowing a plurality of function inputs with a limited number of General Purpose Input/Outputs (GPIOs) in a portable terminal.

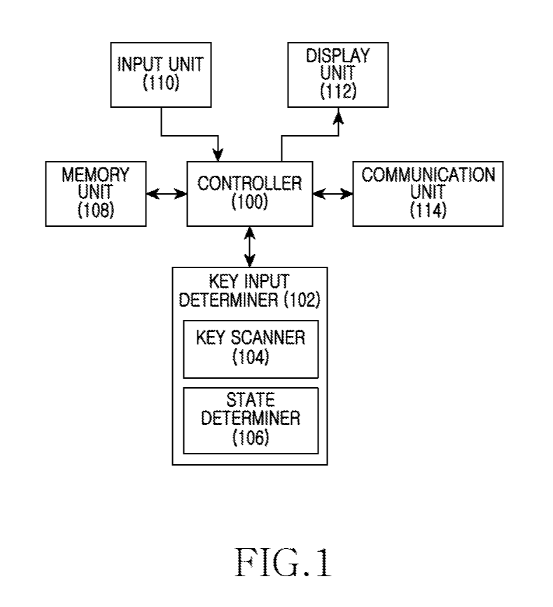

FIG. 1 is a block diagram of a portable terminal for recognizing a user's key input through key scan according to an exemplary embodiment of the present invention.

The portable terminal of FIG. 1 may include a controller 100, a key input determiner 102, a memory unit 108, an input unit 110, a display unit 112, and a communication unit 114. The key input determiner 102 may further include a key scanner 104 and a state determiner 106. The portable terminal may include additional units that are not illustrated here merely for sake of clarity. Similarly, the functionality of two or more of the above units may be integrated into a single component.

The controller 100 of the portable terminal controls operations of the portable terminal. For example, the controller 100 processes and controls voice telephony and data communication. In addition, the controller 100 performs a key scan process using two input signals (e.g., a high signal and a low signal), thus efficiently using a limited number of GPIOs (i.e., achieving the same effect as using numerous GPIOs).

The controller 100 processes to recognize different key inputs in the same interval using the plurality of the input signals (e.g., the high signal and the low signal), instead of a key scan method of the related art which recognizes the key in the interval of the detected signal output using a single input signal (e.g., the input signal corresponding to the high signal).

For doing so, upon detecting the user's key input through the key scan, the controller 100 determines the state of the input signal and determines the function corresponding to the input signal state.

That is, the controller 100 classifies the key input detected in the key scan process to one function according to a first situation and another function according to a second situation, and processes to recognize the user's key input as one of a plurality of different key inputs according to the input signal state indicating the first situation and the second situation.

The key input determiner 102 processes to recognize the user's key input through the key scan under the control of the controller 100.

The key input determiner 102, which includes an inverter for converting the high input signal into the low signal for the key scan process, performs the key scan using the high input signal and performs the key scan using the low input signal converted by the inverter.

More specifically, when sensing the key input in the key scan process, the key input determiner 102 processes to determine the state of the input signal and to determine the key input intended by the user.

The key scanner 104 of the key input determiner 102 determines the user's key input by scanning rows or columns and determining the interval of the output port generating the high signal, or detects the key input by sequentially scanning the output interval of the row or the column.

Upon detecting the user's key input in the key scan process, the state determiner 106 of the key input determiner 102 determines the state of the input signal. In more detail, the state determiner 106 determines whether the key scanner 104 detects the key input using the high input signal, or using the low input signal.

The memory unit 108 includes at least one of a Read Only Memory (ROM), a Random Access Memory (RAM), a flash ROM, and the like. The ROM contains microcodes and reference data of a program for the processing and the controlling of the controller 100 and the key input determiner 102.

The RAM, which is a working memory of the controller 100, stores temporary data generated during the program execution. The flash ROM stores updatable data such as phonebook, outgoing messages, and incoming messages.

The input unit 110 includes a plurality of function keys such as number buttons 0-9, a menu button, a cancel button, an OK button, a call button, an end button, an Internet access button, navigation key buttons, letter input keys, and the like. The input unit 110 provides the controller 100 with key input data corresponding to the key pressed by the user.

The display unit 112 displays status information, letters, videos, and still images in the operations of the portable terminal. The display unit 112 can employ a color Liquid Crystal Display (LCD). When the display unit 112 includes a touch input device and is applied to a touch-type portable terminal, the display unit 112 can be used as an input device.

The communication unit 114 processes to send and receive radio signals of the input and output data over an antenna (not illustrated). For example, in the transmission, the communication unit 114 channel-codes, spreads, Radio Frequency (RF)-processes, and sends data to transmit. In the reception, the communication unit 114 converts the received RF signal into a baseband signal and restores the data by de-spreading and channel-decoding the baseband signal.

While the controller 100 of the portable terminal can function as the key input determiner 102, they are separately illustrated and described herein to distinguish their own functions for convenience in description, not to limit the scope of the invention. One skilled in the art shall appreciate that various modifications can be made without departing from the scope and spirit of the invention. For example, the controller 100 may process all of the functions of the key input determiner 102.

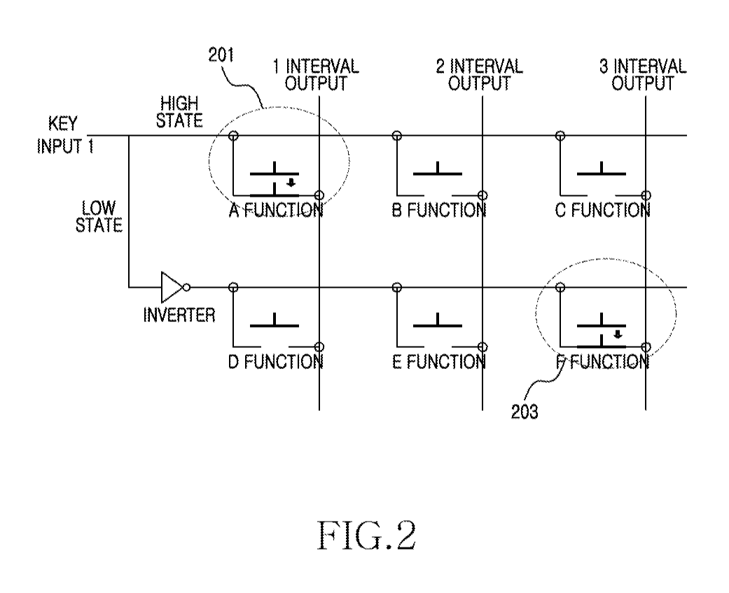

FIG. 2 depicts a key input determiner according to an exemplary embodiment of the present invention.

The key input determiner 102 of FIG. 2 includes the inverter as stated above. The inverter converts the high input signal into the low signal to distinguish between the input signals of the two types as described earlier.

The key input determiner 102 performs the key scan process on each interval. Herein, the interval indicates the output port for the input signal. The key input determiner 102 may determine the user's key input by determining the interval generating the high signal among the multiple intervals or by sequentially applying the key scan to the intervals.

When detecting the key input of the user during the key scan process, the key input determiner 102 determines the state of the input signal and determines whether the key input is detected with the output value generated by the high input signal or whether the key input is detected with the output value generated by the low input signal.

More specifically, a portable terminal of the related art determines the user's key input using the output signal generated only with the input signal of one type (e.g., the high input signal), whereas the present portable terminal attempts to address the shortcoming of using a limited number of GPIOs by determining the user's key input using the output signal generated with the two input signals (e.g., the high input signal and the low input signal).

For example, the key input determiner 102 determines the output of the first interval in the key scan process. Upon detecting the user's key input, the key input determiner 102 examines whether the input signal value is high or low.

This implies that the key detected in the first interval indicates the input for the different functions according to the input signal value. For example, when the user's key input is detected in the first interval, the key input determiner 102 may determine as the key input for an ‘A’ function according to the high input signal and the key input for a ‘D’ function according to the low input signal. The key input determiner 102 may determine the key input which conducts the ‘A’ function according to the high input signal and the ‘D’ function according to the low input signal. When the key input determiner 102 detects the user's key input in the first interval and then determines the high input signal 201 as shown in FIG. 2, the user's key input can be determined as the key input for the ‘A’ function. When the key input determiner 102 detects the user's key input in the third interval and then determines the low input signal 203, the user's key input can be determined as the key input for an ‘F’ function.

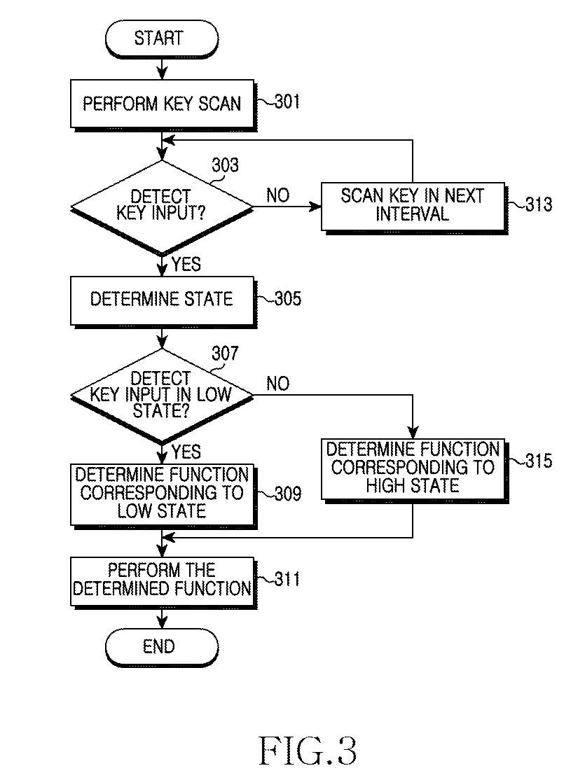

FIG. 3 is a flowchart of a method for recognizing a user's key input through a key scan in a portable terminal according to an exemplary embodiment of the present invention.

The portable terminal carries out the key scan to recognize the key pressed by the user. The method according to the related art adopts the key matrix scheme to recognize the pressed key by sequentially scanning one row or column, but needs to use the plurality of the GPIOs.

To address that problem, the portable terminal of an exemplary embodiment of the present invention processes to fulfill the key scan using the two input signals (e.g., the high input signal and the low input signal).

More specifically, the portable terminal recognizes the key pressed by the user using the high signal output detected when the high signal and the low signal are input, rather than recognizing the key of the interval of the high signal output while the high signal is input according to the key scan method of the related art.

As explained earlier, the portable terminal includes the inverter for converting the input high signal into the low signal for the key can using the two input signals.

The portable terminal performs the key scan in step 301 and then determines whether the user's key input is detected in step 303.

Herein, the keys of the portable terminal are connected to the resistor. When the user issues the key input, the portable terminal controls to detect the user's key input by determining the output port of the high signal.

When not detecting the key input in step 303, the portable terminal determines whether the key input according to the key scan process is detected in the next interval in step 313 and then repeats the step 303. Herein, the portable terminal detects the user's key input by determining the output port generating the high signal amongst the plurality of the output ports. Hereinafter, the portable terminal divides the output ports to the respective output intervals and examines whether the high signal for detecting the key input exists in each output interval. That is, the portable terminal can determine the user's key input by scanning the row or the column and determining the interval of the output port generating the high signal, or by sequentially scanning the output interval of the row or the column.

Meanwhile, upon detecting the key input in step 303, the portable terminal determines the state of the input signal in step 305.

Herein, the state of the input signal indicates the state of the input signal which generates the high output signal to determine the user's key input in the key scan process. The portable terminal of the related art determines the user's key input using the output signal generated with only the high input signal, whereas the portable terminal according to an exemplary embodiment of present invention determines the user's key input using the output signal generated with not only the high input signal but also the low input signal. Hence, the state of the input signal can be divided into the state of the high input signal and the state of the low input signal.

In step 307, the portable terminal determines whether the key input is detected in the low input signal state.

When determining the key input in the low input signal state in step 307, the portable terminal determines the function corresponding to the low input signal in step 309.

When determining the key input in the high input signal state in step 307, the portable terminal determines the function corresponding to the high input signal in step 315.

Herein, the portable terminal may determine the function corresponding to the input signal state based on Table 1.

TABLE 1

| 1^{st} interval | | 2^{nd} interval | | 3^{rd} interval | |
|---|---|---|---|---|---|
| High state | Low state | High state | Low state | High state | Low state |
| A function | D function | B function | E function | C function | F function |

That is, assuming that the portable terminal detects the key input in the first interval through the key scan process, the portable terminal can determine the key input for the ‘A’ function and the key input for the ‘D’ function.

As mentioned earlier, the portable terminal determines whether the user inputs the key for the ‘A’ function or the key for the ‘D’ function by determining the state of the input signal which generates the output signal to determine the user's key input in the key scan process.

For example, when the portable terminal detects the key input of the third interval while the high input signal is used, the user's key input may be determined as the key input for a ‘C’ function.

When the portable terminal detects the key input of the first interval while the low input signal is used, the user's key input can be determined as the key input for the ‘D’ function.

The portable terminal determining the function for the input signal executes the determined function in step 311 and then finishes this process.

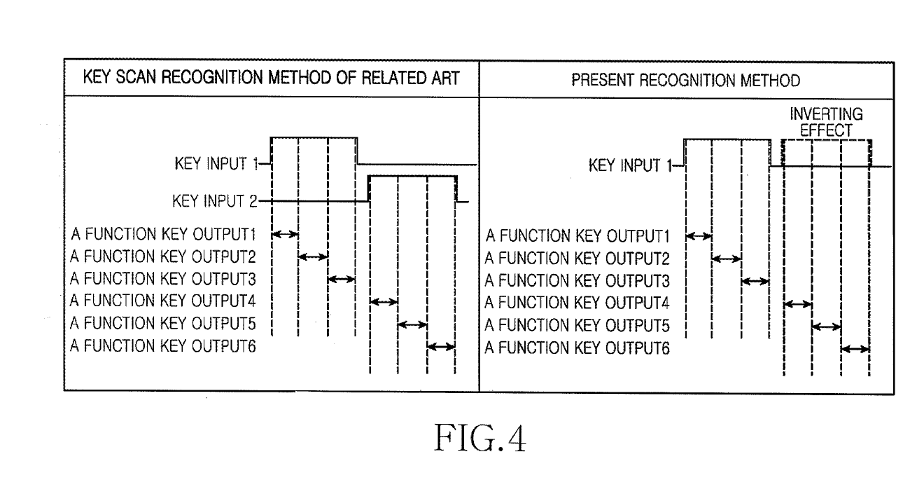

FIG. 4 is a diagram for comparing a key scan method according to an exemplary embodiment of the present invention with a key scan method according to the related art.

The key scan method of the general portable terminal outputs X-ary output ports one by one, scans Y-ary input ports crossing over the output ports in a grid pattern, and thus recognizes the overlapping key.

Accordingly, the GPIO pins of a portable terminal are defined to the value X+Y. Since a great number of keys are used to implement a QWERTY keypad, the value X+Y increases.

In more detail, when the high signal is input, the portable terminal of the related art determines the high output signal and recognizes the key input by the user. In contrast, even when the low signal is input, the portable terminal of an exemplary embodiment of the present invention determines the high output signal and generates the plurality of key recognition matrixes with the a number of limited GPIOs, thus reducing the necessary GPIO pins for the key scan.

For example, when 40 keys are given, the portable terminal of the related art uses 13 (=8+5) GPIO pins based on 8*5=40, whereas the portable terminal of an exemplary embodiment of the present invention using the inverter uses merely 9 (=4+5) GPIO pins based on 4 (*2)*5=40.

As set forth above, the apparatus and the method for performing the plurality of the functions with a limited number of GPIOs by defining the key input corresponding to the state of the multiple input signals in the portable terminal, carry out the plurality of the functions with the limited number of GPIOs by classifying the input signal state into a plurality of states and conducting different operations according to the state of the input signal of each interval. Therefore, the cost incurred due to the supplement of the GPIO extension device can be addressed.

While the invention has been described with reference to certain exemplary embodiments thereof, it will be understood by those skilled in the art that various changes in form and details may be made therein without departing from the spirit and scope of the invention as defined by the appended claims and their equivalents.

What is claimed is:

1. An apparatus for improving performance of a key scan in a portable terminal, the apparatus comprising:
a controller for setting one or more intervals for a key scan process, for classifying a state of a signal input in each interval as one of a first state and a second state, and for setting one of a plurality of different functions according to the state and the interval of the input signal; and
a key input determiner for, when detecting a key input of a user during the key scan process, recognizing one of a plurality of different key inputs according to the state of the input signal, and for determining a function corresponding to the recognized key input,
wherein the controller performs the determined function.

2. The apparatus of claim 1, wherein the key input determiner determines the state of the input signal and the interval of the detected key input, and determines the function corresponding to the state and the interval of the input signal.

3. The apparatus of claim 2, wherein the key input determiner determines the function corresponding to the state and the interval of the input signal based on the following table:

| 1^{st} interval | | 2^{nd} interval | | 3^{rd} interval | |
|---|---|---|---|---|---|
| High state | Low state | High state | Low state | High state | Low state |
| A function | D function | B function | E function | C function | F function |

4. The apparatus of claim 1, wherein the state of the signal input in each interval comprises a first state with a high input signal and a second state with a low input signal, or a first state with a low input signal and a second state with a high input signal.

5. The apparatus of claim 4, wherein the key input determiner performs the key scan process using the high input signal, converts the high input signal into the low input signal, and determines the state of the input signal by performing the key scan process using the converted low input signal.

6. The apparatus of claim 1, wherein the key scan process sets the one or more intervals for the key scan process as a plurality of rows and columns, and then determines the interval of the one or more intervals generating the high signal among the rows or the columns or determines the interval of the one or more intervals generating the high signal by sequentially scanning the rows or the columns.

7. A method for improving performance of a key scan in a portable terminal, the method comprising:
setting one or more intervals for a key scan process;
classifying a state of a signal input in each interval as one of a first state and a second state;
setting one of a plurality of different functions according to the state and the interval of an input signal;
when detecting a key input of a user during the key scan process, recognizing one of a plurality of different key inputs according to the state of the input signal; and
performing a function corresponding to the recognized key input.

8. The method of claim 7, wherein, when detecting the key input of the user during the key scan process, the recognizing of the one of the plurality of different key inputs according to the state and the interval of the input signal comprises:
determining the state of the input signal;
determining the interval of the detected key input; and
determining the function corresponding to the state and the interval of the input signal.

9. The method of claim 8, wherein the function corresponding to the state and the interval of the input signal is determined based on the following table:

| 1^{st} interval | | 2^{nd} interval | | 3^{rd} interval | |
|---|---|---|---|---|---|
| High state | Low state | High state | Low state | High state | Low state |
| A function | D function | B function | E function | C function | F function |

10. The method of claim 7, wherein the state of the input signal comprises a first state with a high input signal and a second state with a low input signal, or a first state with a low input signal and a second state with a high input signal.

11. The method of claim 10, further comprising determining the state of the input signal, where the determining of the state of the input signal comprises:
performing the key scan process using the high input signal;
converting the high input signal to the low input signal; and
performing the key scan process using the converted low input signal.

12. The method of claim 7, wherein the key scan process comprises:
setting the one or more intervals for the key scan process to a plurality of rows and columns;
determining the interval of the one or more intervals generating the high signal among the rows or the columns; and
determining the interval of the one or more intervals generating the high signal by sequentially scanning the rows or the columns.

13. A method for improving performance of a key scan in a portable terminal, the method comprising:
associating a different function with each of a plurality of states of a key input signal input during each of a plurality of intervals;
determining a function corresponding to the state and the interval of a key input signal input during the key scan; and
performing the determined function.

14. The method of claim 13, wherein the different functions are associated with each of the plurality of states of the signal input during each of the plurality of intervals based on the following table:

| 1^{st} interval | | 2^{nd} interval | | 3^{rd} interval | |
|---|---|---|---|---|---|
| High state | Low state | High state | Low state | High state | Low state |
| A function | D function | B function | E function | C function | F function |

15. The method of claim 13, wherein the plurality of states of the key input signal comprises a first state with a high input signal and a second state with a low input signal, or a first state with a low input signal and a second state with a high input signal.

16. The method of claim 13, wherein the determining of the function corresponding to the state and the interval of the key input signal input during the key scan comprises:
determining the state of the key input signal input during the key scan;
determining the interval of key input signal input during the key scan; and
determining the function corresponding to the determined state and the determined interval of the key input signal input during the key scan.

17. The method of claim 13, wherein the key scan is performed using a high input signal, the high input signal is converted into a low input signal, and the key scan is performed using the converted low input signal.
